(19) United States
(12) Patent Application Publication
(10) Pub. No.: US 2006/0170041 A1
(43) Pub. Date: Aug. 3, 2006

(54) MOSFET and optical coupling device having the same

(75) Inventors: Takeshi Uchihara, Saitama-ken (JP); Yasunori Usui, Kanagawa-ken (JP); Hideyuki Ura, Hyogo-ken (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: Kabushiki Kaisha Toshiba, Tokyo (JP)

(21) Appl. No.: 11/335,602

(22) Filed: Jan. 20, 2006

(30) Foreign Application Priority Data
Jan. 20, 2005 (JP) 2005-12443

(51) Int. Cl. H01L 29/76

(52) U.S. Cl. 257/339

(57) ABSTRACT

In various aspects, a MOSFET may include a semiconductor region of a first conductivity type; a first semiconductor region of a second conductivity type provided in the semiconductor region; a second semiconductor region of the first conductivity type provided in the semiconductor region, the second semiconductor region having a higher impurity concentration than the semiconductor region; a third semiconductor region of the second conductivity type provided on the second semiconductor region; a fourth semiconductor region of the second conductivity type configured to be contact with the first semiconductor region and the third semiconductor region, the fourth semiconductor region having a lower impurity concentration than the first semiconductor region and the third semiconductor region; a gate electrode provided on the fourth semiconductor region via a gate insulating layer, an edge of the gate electrode spaced from a junction between the first semiconductor region and the fourth semiconductor region.

### CROSS REFERENCE TO RELATED APPLICATION

This application is based upon and claims the benefit of priority from Japanese Patent Application No. 2005-12443, filed on Jan. 20, 2005, the entire contents of which are incorporated herein by reference.

### BACKGROUND OF THE INVENTION

A semiconductor element such as a power MOSFET requires a high breakdown voltage and a low ON resistance. However, it is not easy for the semiconductor element to be obtained having the high breakdown voltage and the low ON resistance.

In an enhancement-type (normally OFF-type) MOSFET, a MOSFET structure for attaining a high breakdown voltage and a low ON resistance is shown in, for example, Japanese Patent Laid Open Publication No. 9-205201.

However, in a depletion-type (normally ON-type) MOSFET, a similar structure is not known. Although a MOSFET structure of an enhancement-type may be adapted to a MOSFET structure of a depletion-type in order to make the high break down voltage, the effect of the transferring the structure is not good. Namely, the MOSFET structure of the enhancement-type is not simply transferred to that of the depletion-type, and vice versa.

In a depletion-type MOSFET, another structure for obtaining high breakdown voltage is required.

### SUMMARY

In one aspect of the invention, a MOSFET may include a semiconductor region of a first conductivity type; a first semiconductor region of a second conductivity type provided in the semiconductor region; a second semiconductor region of the first conductivity type provided in the semiconductor region, the second semiconductor region having a higher impurity concentration than the semiconductor region; a third semiconductor region of the second conductivity type provided on the second semiconductor region; a fourth semiconductor region of the second conductivity type configured to be contact with the first semiconductor region and the third semiconductor region, the fourth semiconductor region having a lower impurity concentration than the first semiconductor region and the third semiconductor region; and a gate electrode provided on the fourth semiconductor region via a gate insulating layer, an edge of the gate electrode spaced from a junction between the first semiconductor region and the fourth semiconductor region.

In another aspect of the invention, a MOSFET may include a semiconductor region of a first conductivity type; a first semiconductor region of a second conductivity type provided in the semiconductor region; a second semiconductor region of the first conductivity type provided in the semiconductor region, the second semiconductor region having a higher impurity concentration than the semiconductor region; a third semiconductor region of the second conductivity type provided on the second semiconductor region; a fourth semiconductor region of the second conductivity type configured to be contact with the first semiconductor region and the third semiconductor region, the fourth semiconductor region having a lower impurity concentration than the first semiconductor region and the third semiconductor region; and a gate electrode provided on the fourth semiconductor region via a gate insulating layer, an edge of the gate electrode spaced from a junction between the first semiconductor region and the fourth semiconductor region, wherein an impurity concentration of the fourth semiconductor region is no less than 0.5×10¹² (cm−2).

### BRIEF DESCRIPTIONS OF THE DRAWINGS

FIG. 1 is a cross sectional view of a MOSFET in accordance with a first embodiment of the present invention.

FIG. 2 is a cross sectional view of a MOSFET in accordance with a modified first embodiment of the present invention.

FIG. 3 is a graph showing a relationship between the distance X shown in FIG. 1 and the breakdown voltage Vdss.

FIG. 4 is an enlarged graph showing a relationship between the distance X shown in FIG. 3 and the breakdown voltage Vdss.

FIG. 5 is a graph showing the breakdown voltage with the distance X and an impurity dose of a channel region Qd as the parameter, by response surface methodology.

FIG. 6 is a graph showing a relationship between a threshold voltage Vth of the MOSFET as shown in FIG. 1 and the impurity dose of a channel region Qd.

FIG. 7 is a graph showing an ON resistance with the distance X and impurity dose Qd as the parameter, by response surface methodology.

FIG. 8 is a circuit diagram of a photo coupler having a MOSFET of FIG. 1.

FIG. 9 is a cross sectional view of a MOSFET in accordance with a modified first embodiment of the present invention.

FIG. 10 is a cross sectional view of a MOSFET in accordance with a modified first embodiment of the present invention.

### DETAILED DESCRIPTION OF THE INVENTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as follows.

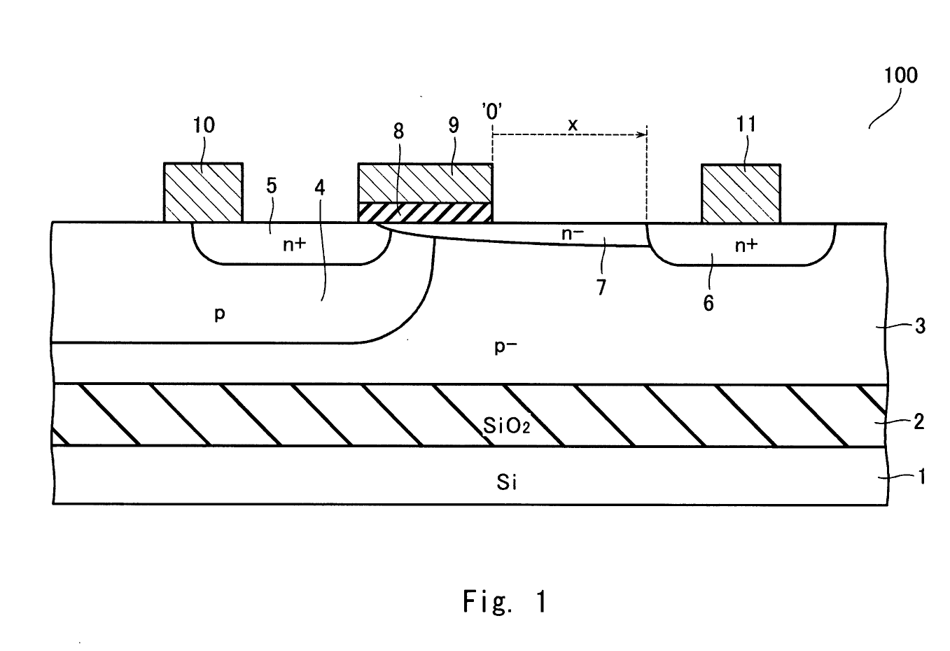

A first embodiment of the present invention will be explained hereinafter with reference to FIG. 1 to FIG. 10.

FIG. 1 is a cross sectional view of a MOSFET 100 in accordance with a first embodiment of the present invention.

The MOSFET 100 is provided on an SOI substrate, which is provided on a Si semiconductor substrate 1 via an SiO2 layer 2. A P-type active region 3 is provided on the SiO2 layer 2. A P-type base region 4, an N+-type source region 5, an N+-type drain region 6 and an N-channel region 7, which are formed by using photo lithography, are provided in the active layer 3. A gate electrode 9 is provided on the channel region 7 via a gate insulating layer 8. A source electrode 10 and a drain electrode 11 are provided on the source region 5 and the drain region 6, respectively. The N-type MOSFET 100 is provided as mentioned above.

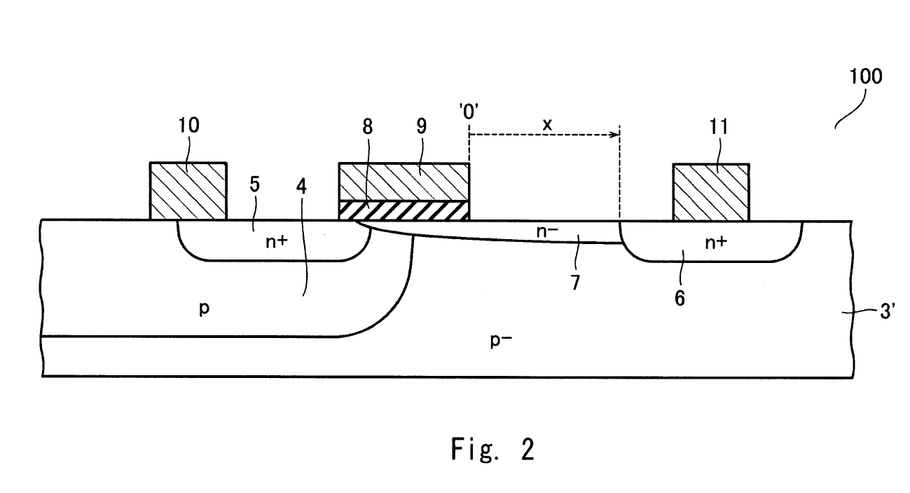

Alternatively, a P-type MOSFET may be provided by changing a conductivity type of the N-type MOSFET 100. As shown in FIG. 2, the MOSFET 100 may be provided on a bulk substrate 3′ instead of the SOI substrate.

A structure of the MOSFET 100 will be explained with the SOI substrate as FIG. 1 hereinafter. However, a MOSFET 100 explained hereinafter may be provided on the bulk substrate.

The channel region 7, which is provided in the active region 3 between the source region 5 and the drain region 6, may be formed by diffusing an N-type impurity such as As among other approaches. An impurity concentration of the channel region 7 may be no less than 0.5×10¹² (cm−2). A junction between the channel region 7 and the drain region 6 is spaced a distance X from a drain side edge (right edge in FIG. 1) of the gate electrode 9. Thus a part of the channel region 7 (left side of the channel region 7 in FIG. 1), which is provided under the gate electrode 9, functions as a channel of the depletion-type MOSFET 100, and a part of the channel region 7, which is shown in a right side of the channel region 7 in FIG. 1, functions as a extension region of the drain region 6. In this embodiment, a position of the junction surface between the channel region 7 and the drain region 6 may be defined as a position where the inclination of the impurity is equal to or smaller than a predetermined value.

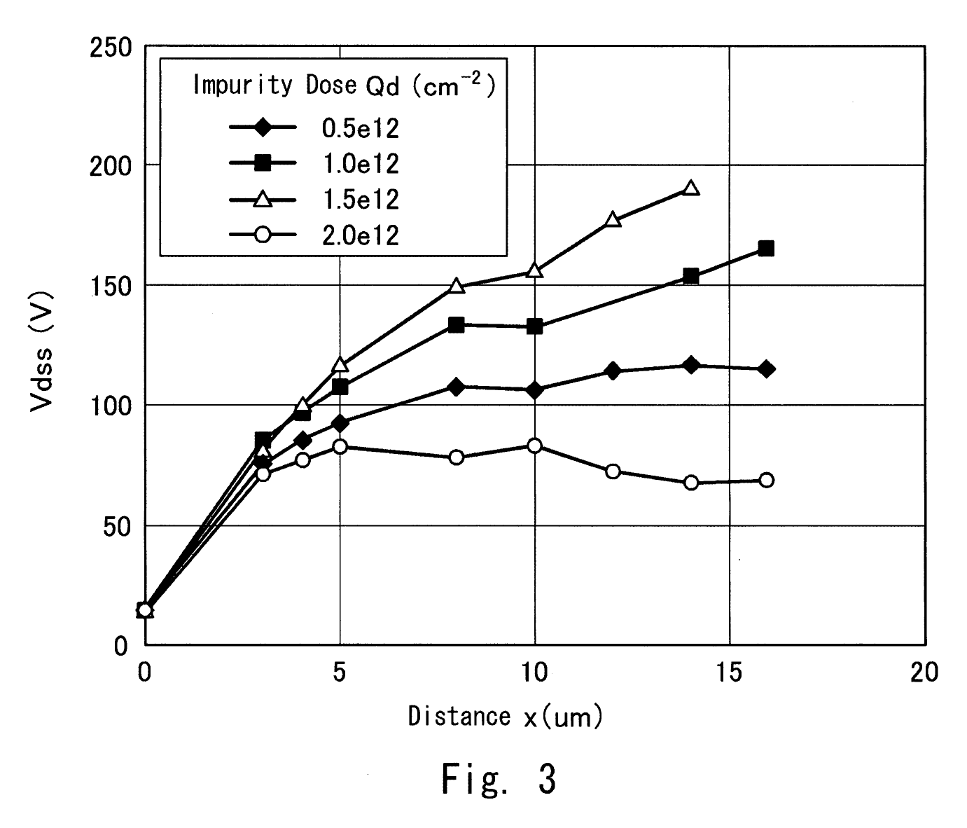

FIG. 3 is a graph showing a relationship between the distance X shown in FIG. 1 and the breakdown voltage Vdss.

As shown in FIG. 3, the breakdown voltage Vdss is larger as the distance X is larger. When the distance X is no less than 5 micrometers, the breakdown voltage Vdss is about 100 V, with regardless of the impurity dose Qd. The breakdown voltage Vdss is increased as the distance X increases. However, the breakdown voltage Vdss is saturated when the distance X is no less than 8 micrometers.

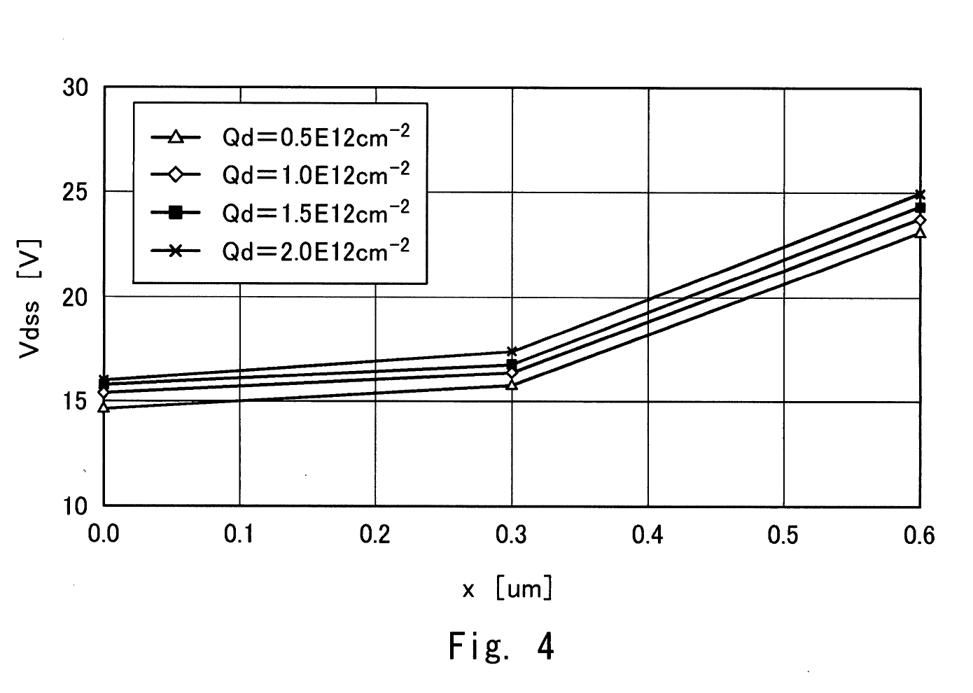

FIG. 4 is an enlarged graph of FIG. 3. FIG. 4 shows a part of the FIG. 3, which shows the distance of no less than 0 micrometer and no more than 0.6 micrometers. Despite the impurity dose Qd (no less than 0.5×10¹² (cm−2)) when the distance is no less than 0.3 micrometers, the breakdown voltage Vdss is no less than 15 V. This breakdown voltage is high enough for a low breakdown voltage MOSFET.

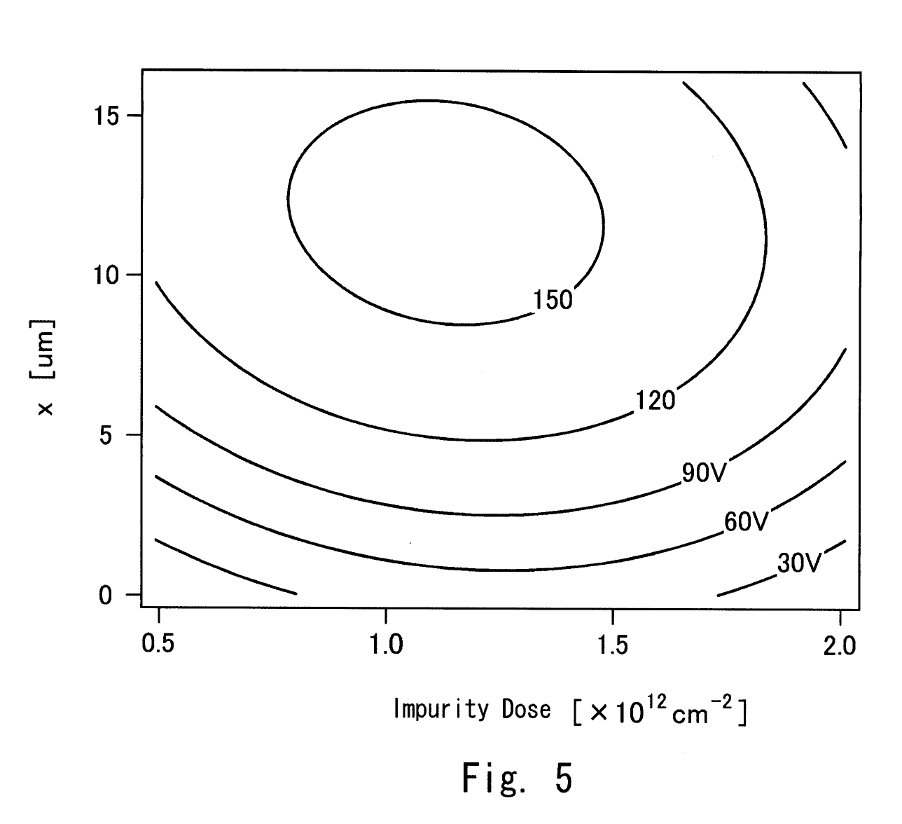

FIG. 5 is a graph by response surface methodology, showing the breakdown voltage with the distance X and an impurity dose of a channel region Qd as the parameter.

As shown in FIG. 5, the highest breakdown voltage Vdss is obtained, when the impurity dose Qd is about 0.8×10¹² (cm−2)−1.5×10¹² (cm−2) and the distance X is no less than 8 micrometers.

The breakdown voltage Vdss may be reduced if the impurity dose Qd is too small or too large. In case the impurity dose Qd is too large, it is hard for the depleted region to be extended and the breakdown may occur by the electric field concentration at an edge of the gate electrode 9. In case the impurity dose Qd is too small, it is easy for the depleted region to be extended and to punch through to the drain region 6, and the breakdown may occurr by the electric field concentration at an edge of the drain region 6.

The reason for the saturation of the breakdown voltage Vdss at the distance X being no less than 8 micrometers will be explained. In case the distance X is small, the breakdown voltage is low since the depleted region punches through to the drain region 6. In case the distance X is large, the breakdown occurs since the electric field concentration, which is a reason of the saturation of the breakdown voltage, is not eased at the edge of the gate electrode 9.

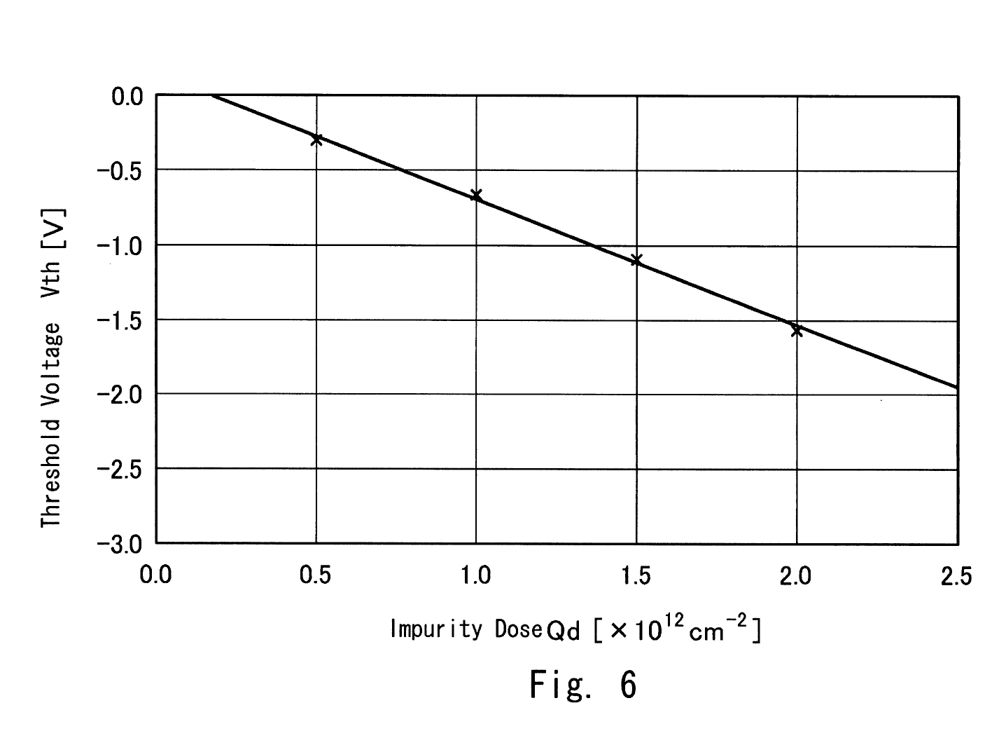

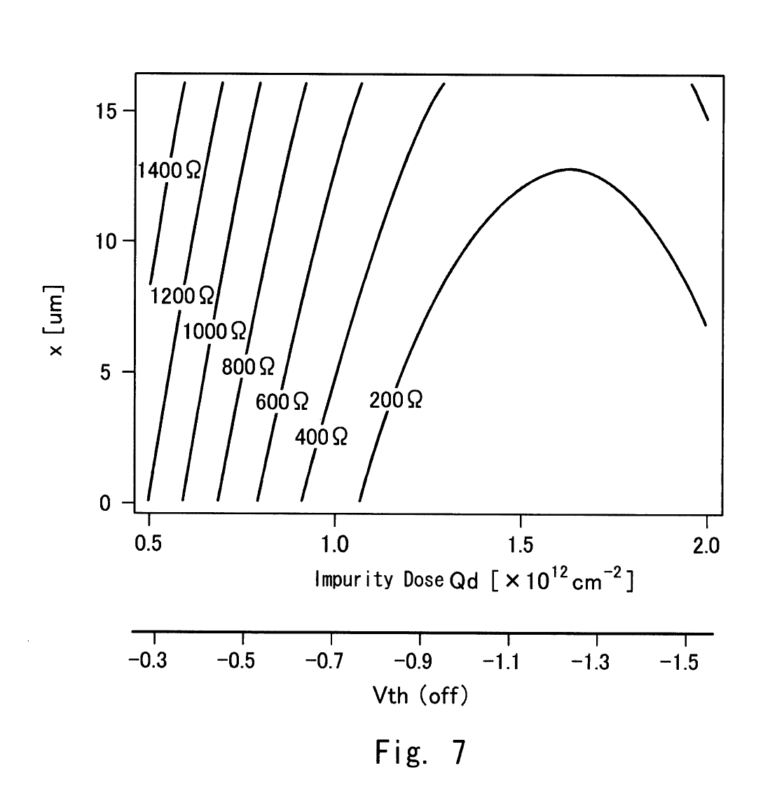

An optimal distance X and the impurity dose Qd are mentioned above in an aspect of improving the breakdown voltage Vdss. An optimal distance X and the impurity concentration Qd will be described hereinafter with reference to FIGS. 6 and 7 in an aspect of reducing the ON resistance.

FIG. 6 is a graph showing a relationship between a threshold voltage Vth of the MOSFET as shown in FIG. 1 and the impurity dose of a channel region Qd. As shown in FIG. 6, an absolute value of the threshold voltage, which is a negative value, is increased substantially in proportion to the impurity dose Qd into the channel region 7.

FIG. 7 is a graph showing an ON resistance with the distance X and impurity dose Qd as the parameter, by response surface methodology. The vertical axis is the impurity dose Qd and the threshold voltage Vth, which is in proportion to the impurity dose Qd. As shown in FIG. 7, in case the impurity dose is decreased or the absolute value of the threshold voltage Vth is decreased, the ON resistance is increased to be no less than 1 kΩ with the impurity dose Qd being less than 0.5×10¹² (cm−2). This value is not suitable for practical use of the MOSFET. It may be necessary that the impurity dose Qd is no less than 0.5×10¹² (cm−2) in order to reduce the ON resistance.

In the MOSFET as shown in FIG. 1, the impurity dose into the channel region Qd may be no less than 0.5×10¹² (cm−2) and the distance X may be designed based on the required breakdown voltage Vdss.

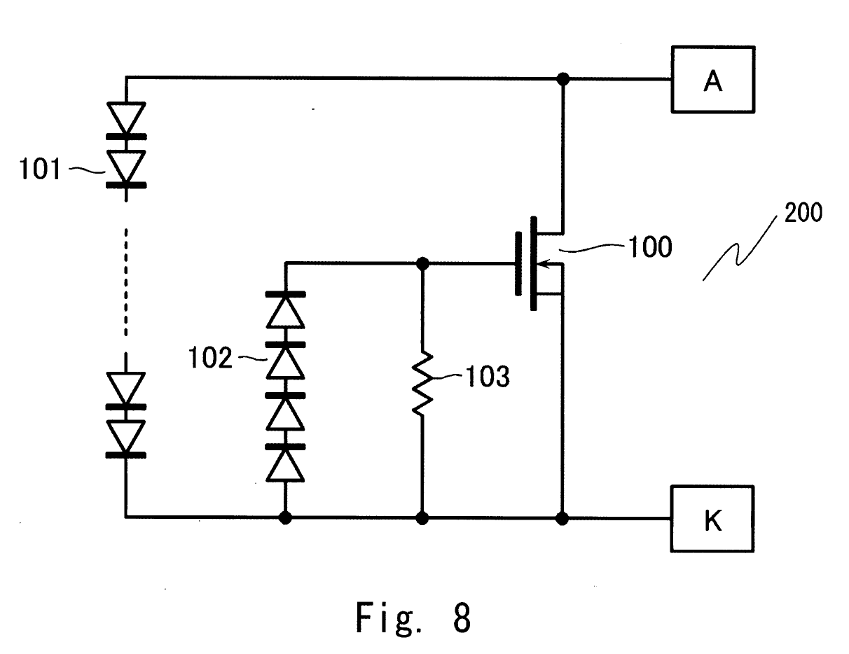

FIG. 8 is a circuit diagram of a photo coupler 200 having the MOSFET of FIG. 1. In the photo coupler 200, the MOSFET 100, a photodiode array 101 and 102, and a resistance 103 is provided. The photodiode array 101 is connected between a source and a drain of the MOSFET 100. A photoelectric voltage is generated when the photodiode array 101 receives light from an LED (not shown in FIG. 8). The photodiode array 102 is connected between a gate and the source of the MOSFET 100. The MOSFET 100 is turned OFF by a photoelectric voltage of the photodiode array 102, when the photodiode array 102 receives light. The resistance 103 is connected parallel to the photodiode array 102. The resistance 103 consumes the photoelectric voltage of the photodiode array 102 after the MOSFET 100 is turned OFF.

A characteristic such as the threshold voltage is likely to be varied in the photo coupler 200, when light is irradiated to the MOSFET 100 or a mobile ion appears in a surface of the MOSFET 100.

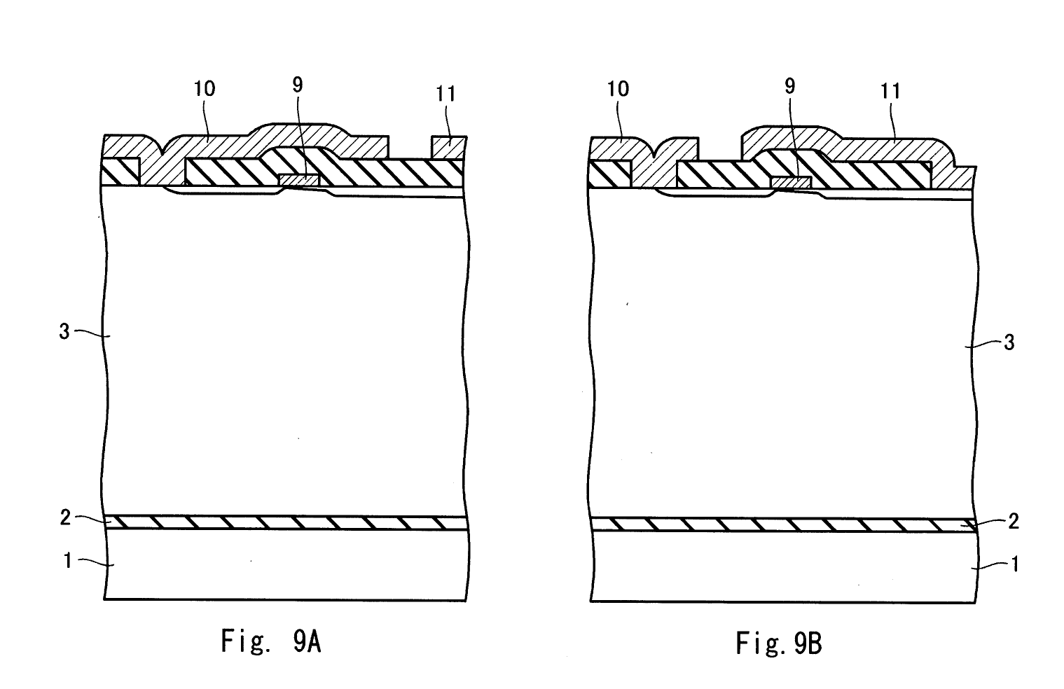

As shown in FIGS. 9A and 9B, the source electrode 10 or the drain electrode 11 may be extended to cover the gate electrode 9 for blocking the light or the mobile ion, respectively. A length of the extended part of the source electrode 10 or the drain electrode 11 may be designed at a suitable length. In case the length is too short, the effect of the blocking is small. In case the length is too long, the depleted region is hardly extended at the extended part of the source electrode 10 or the drain electrode 11, and the breakdown voltage is reduced by the electric field concentration at the extended part.

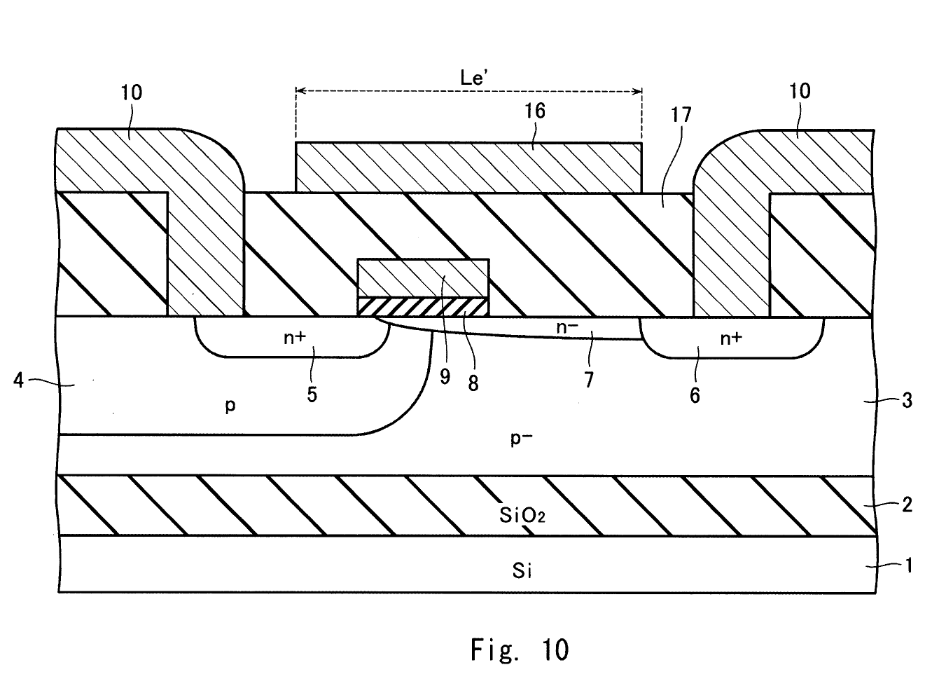

FIG. 10 is a cross-sectional view of a MOSFET in accordance with a modified first embodiment of the present invention. In FIG. 10, a metal electrode 16, which blocks light or a mobile ion, is provided on an interlayer dielectric 17. The metal electrode 16 is insulated from the source electrode 10 and the drain electrode 11 by the interlayer dielectric 17. The metal electrode 16 is not connected to each electrode and is in a floating state. A thickness of the interlayer dielectric 17 may be decided on account of a required breakdown voltage. For example, it may be necessary that the thickness is no less than 3 micrometers when the required breakdown voltage is 147 V.

The structure as shown in FIG. 10, even if a length Le′ of the metal electrode 16 is longer, the breakdown voltage is not reduced so much. In this aspect, the structure as shown in FIG. 10 can be more effective than that in FIG. 9.

In FIG. 10, the metal electrode 16 extends above the gate electrode 9 and over a periphery of the gate electrode 9. However, the metal electrode 16 may be provided covering most of or a part of the gate electrode 9, the source region 5, and the drain region 6, or combinations thereof.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A MOSFET, comprising:
a semiconductor region of a first conductivity type;
a first semiconductor region of a second conductivity type provided in the semiconductor region;
a second semiconductor region of the first conductivity type provided in the semiconductor region, the second semiconductor region having a higher impurity concentration than the semiconductor region;
a third semiconductor region of the second conductivity type provided on the second semiconductor region;
a fourth semiconductor region of the second conductivity type configured to be in contact with the first semiconductor region and the third semiconductor region, the fourth semiconductor region having a lower impurity concentration than the first semiconductor region and the third semiconductor region;
a gate electrode provided on the fourth semiconductor region via a gate insulating layer, an edge of the gate electrode spaced from a junction between the first semiconductor region and the fourth semiconductor region.

2. A MOSFET of claim 1, wherein a impurity concentration of the fourth semiconductor region is no less than 0.8×10¹² (cm⁻²) and no more than 1.5×10¹² (cm−2) and a distance from the edge of the gate to the junction between the first semiconductor region and the fourth semiconductor region is no less than 8 micrometers.

3. A MOSFET of claim 1, wherein the semiconductor region is provided on an insulating layer.

4. A MOSFET of claim 1, wherein a metal electrode being contact to the first semiconductor region or the third semiconductor region extends above but is insulated from the gate electrode.

5. A MOSFET of claim 1, wherein the first conductivity type is P-type and the second conductivity type is N-type.

6. A MOSFET of claim 1, wherein a distance from the edge of the gate to the junction between the first semiconductor region and the fourth semiconductor region is no less than 0.3 micrometers.

7. A MOSFET of claim 1, wherein a distance from the edge of the gate to the junction between the first semiconductor region and the fourth semiconductor region is no less than 5 micrometers.

8. A MOSFET of claim 1, wherein the fourth semiconductor region extends at least to the second semiconductor region.

9. A MOSFET of claim 8, wherein the gate electrode extends over a junction between the fourth semiconductor region and the second semiconductor region via the insulating layer.

10. A MOSFET, comprising:
a semiconductor region of a first conductivity type;
a first semiconductor region of a second conductivity type provided in the semiconductor region;
a second semiconductor region of the first conductivity type provided in the semiconductor region, the second semiconductor region having a higher impurity concentration than the semiconductor region;
a third semiconductor region of the second conductivity type provided on the second semiconductor region;
a fourth semiconductor region of the second conductivity type configured to be contact with the first semiconductor region and the third semiconductor region, the fourth semiconductor region having a lower impurity concentration than the first semiconductor region and the third semiconductor region;
a gate electrode provided on the fourth semiconductor region via a gate insulating layer, an edge of the gate electrode spaced from a junction between the first semiconductor region and the fourth semiconductor region.
wherein an impurity concentration of the fourth semiconductor region is no less than 0.5×10¹² (cm⁻²).

11. A MOSFET of claim 10, wherein a impurity concentration of the fourth semiconductor region is no less than 0.8×10¹² (cm⁻²) and no more than 1.5×10¹² (cm⁻²) and a distance from the edge of the gate to the junction between the first semiconductor region and the fourth semiconductor region is no less than 8 micrometers.

12. A MOSFET of claim 10, wherein the semiconductor region is provided on an insulating layer.

13. A MOSFET of claim 10, wherein a metal electrode is provided one of covering the gate electrode with being contact to the first semiconductor region or the third semiconductor region, and covering the gate electrode with a floating state.

14. A MOSFET of claim 10, wherein a distance from the edge of the gate to the junction between the first semiconductor region and the fourth semiconductor region is no less than 0.3 micrometers.

15. A MOSFET of claim 10, wherein a distance from the edge of the gate to the junction between the first semiconductor region and the fourth semiconductor region is no less than 5 micrometers.

16. A MOSFET of claim 10, wherein the first conductivity type is P type and the second conductivity type is N type.

17. A MOSFET of claim 10, wherein the fourth semiconductor region is junction with the second semiconductor region.

18. A MOSFET of claim 17, wherein the gate electrode is provided on a junction portion between the fourth semiconductor region and the second semiconductor region via the insulating layer.

19. An optical coupling device comprising:
a MOSFET having
a semiconductor region of a first conductivity type;
a first semiconductor region of a second conductivity type provided in the semiconductor region;
a second semiconductor region of the first conductivity type provided in the semiconductor region, the second semiconductor region having a higher impurity concentration than the semiconductor region;
a third semiconductor region of the second conductivity type provided on the second semiconductor region;
a fourth semiconductor region of the second conductivity type configured to be in contact with the first semiconductor region and the third semiconductor region, the fourth semiconductor region having a lower impurity concentration than the first semiconductor region and the third semiconductor region;
a gate electrode provided on the fourth semiconductor region via a gate insulating layer, an edge of the gate electrode spaced from a junction between the first semiconductor region and the fourth semiconductor region.

20. An optical coupling device of claim 19, wherein the MOSFET having an impurity concentration of the fourth semiconductor region no less than 0.5×10¹² (cm⁻²).
